(19) United States
(12) Patent Application Publication
(10) Pub. No.: US 2009/0284931 A1
(43) Pub. Date: Nov. 19, 2009

(54) NESTED FIN INTEGRAL HEAT SINK ASSEMBLY FOR MULTIPLE HIGH POWER ELECTONIC CIRCUIT BOARD MODULES

(75) Inventors: Raymond Floyd Babock, Stewartville, MN (US); Matthew Allen Butterbaugh, Rochester, MN (US); David Roy Motschman, Rochester, MN (US)

Correspondence Address: IBM-ACC-Washington;c/o Myers Andras Sherman LLP, 19900 MacArthur Blvd., Suite 1150, Irvine, CA, 92612, US

(73) Assignee: International Business Machines Corporation, Armonk, NY (US)

(21) Appl. No.: 12/121,582

(22) Filed: May 15, 2008

(51) Int. Cl. H05K 7/20

(52) U.S. Cl. 361/716

(57) ABSTRACT

A method and apparatus for heat sinking for multiple high power circuit board modules, is provided. One implementation involves providing a compact nested fin integral heat sink assembly for each high power circuit board module, and positioning fin sections on the heat sink assembly such that a plurality of nested fin sections emanate from each board side heat spreader plate of the assembly, thereby providing efficient airflow gap, pressure drop, and heat sink base spreading performance. The fin section can be placed essentially directly over high power components on each board module to minimize spreading resistance in a heat sink base of the assembly. The fin sections on each board module side provide channel depth without extending from an opposite side heat sink base, thereby increasing fin surface area for each local region of fins from either heat sink base.

### BACKGROUND OF THE INVENTION

1. Field of the Invention

The present invention relates generally to heat sinking, and in particular to heat sinking for electronic circuit boards.

2. Background Information

Cooling electronic circuit board has grown in importance as more high powered components are packed on to boards in tighter spaces. A conventional cooling approach uses a liquid cooled cold plate with features that allows mounting of inward facing surface of each board to a common cold plate. Heat from the high power electronics on each inward facing surface is carried away via a liquid flowing through cooling channels inside a cold plate assembly. The liquid cooled approach introduces high assembly cost, the risk of leaking fluid damaging the circuit boards, and much higher cost to pump fluid through a closed circuit cooling loop.

### SUMMARY OF THE INVENTION

A method and apparatus for heat sinking for multiple high power circuit board modules, is provided. One embodiment involves providing a compact nested fin integral heat sink assembly for each high power circuit board module, and positioning fin sections on the heat sink assembly such that a plurality of nested fin sections emanate from each board side heat spreader plate of the assembly, thereby providing efficient airflow gap, pressure drop, and heat sink base spreading performance. The fin section can be placed essentially directly over high power components on each board module to minimize spreading resistance in a heat sink base of the assembly, the fin sections on each board module side providing channel depth without extending from an opposite side heat sink base, thereby increasing fin surface area for each local region of fins from either heat sink base.

Other aspects and advantages of the present invention will become apparent from the following detailed description, which, when taken in conjunction with the drawings, illustrate by way of example the principles of the invention.

### BRIEF DESCRIPTION OF THE DRAWINGS

For a fuller understanding of the nature and advantages of the invention, as well as a preferred mode of use, reference should be made to the following detailed description read in conjunction with the accompanying drawings, in which:

FIGS. 1A and 1B show a front view and an isometric view, respectively, of an integral heat sink assembly, according to an embodiment of the invention.

FIG. 2 shows an exploded view of the integral heat sink assembly.

FIG. 3 shows a perspective view of a right side card heat sink of the integral heat sink assembly, with optimized fin sections over high power processor location(s), according to an embodiment of the invention.

FIG. 4 shows a perspective view of a left side card heat sink of the integral heat sink assembly, with optimized fin sections over high power processor locations (four card corners), according to an embodiment of the invention.

FIG. 5 shows an example chassis rail structure in which an integral heat sink assembly according to the invention is installed.

### DESCRIPTION OF THE PREFERRED EMBODIMENTS

The following description is made for the purpose of illustrating the general principles of the invention and is not meant to limit the inventive concepts claimed herein. Further, particular features described herein can be used in combination with other described features in each of the various possible combinations and permutations. Unless otherwise specifically defined herein, all terms are to be given their broadest possible interpretation including meanings implied from the specification as well as meanings understood by those skilled in the art and/or as defined in dictionaries, treatises, etc.

The invention provides a method and apparatus for heat sinking for multiple high power circuit board modules. One embodiment involves providing a compact nested fin integral heat sink assembly for each high power circuit board module, and positioning fin sections on the heat sink assembly such that a plurality of nested fin sections emanate from each board side heat spreader plate of the assembly, thereby providing efficient airflow gap, pressure drop, and heat sink base spreading performance. The fin section can be placed essentially directly over high power components on each board module to minimize spreading resistance in a heat sink base of the assembly, the fin sections on each board module side providing channel depth without extending from an opposite side heat sink base, thereby increasing fin surface area for each local region of fins from either heat sink base.

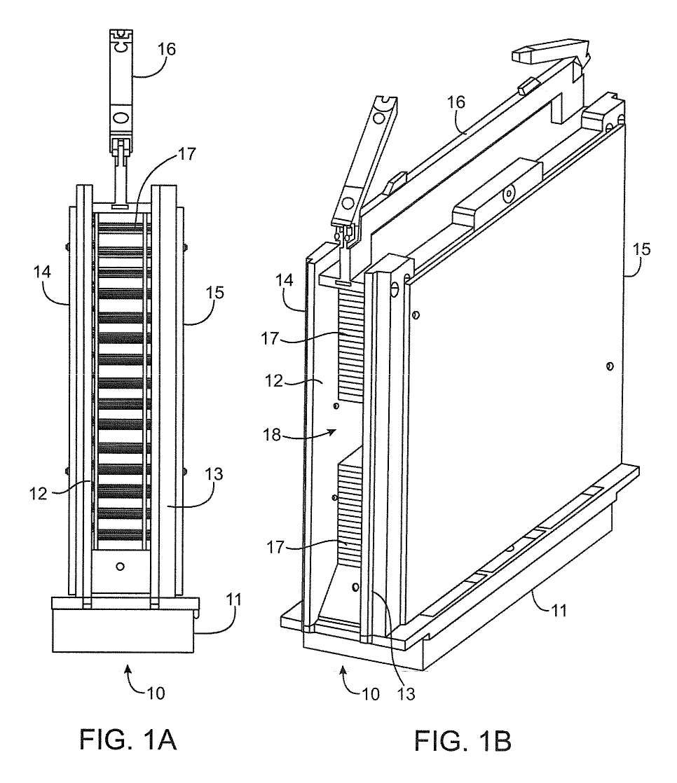

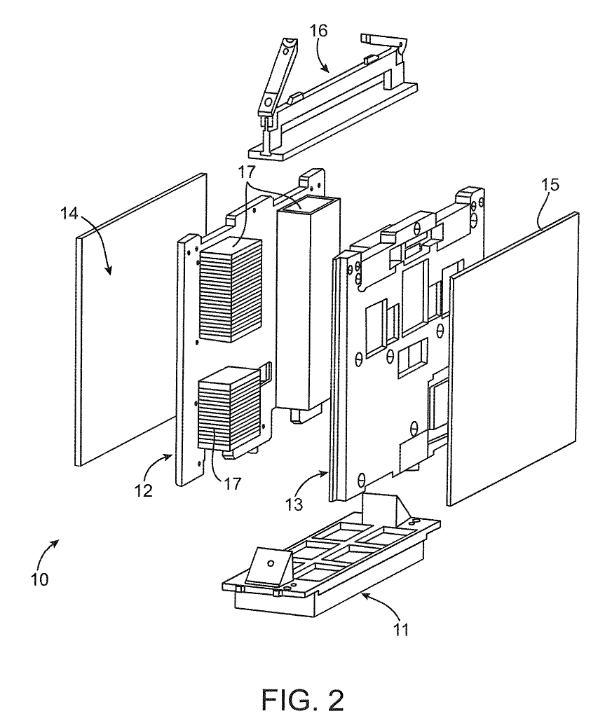

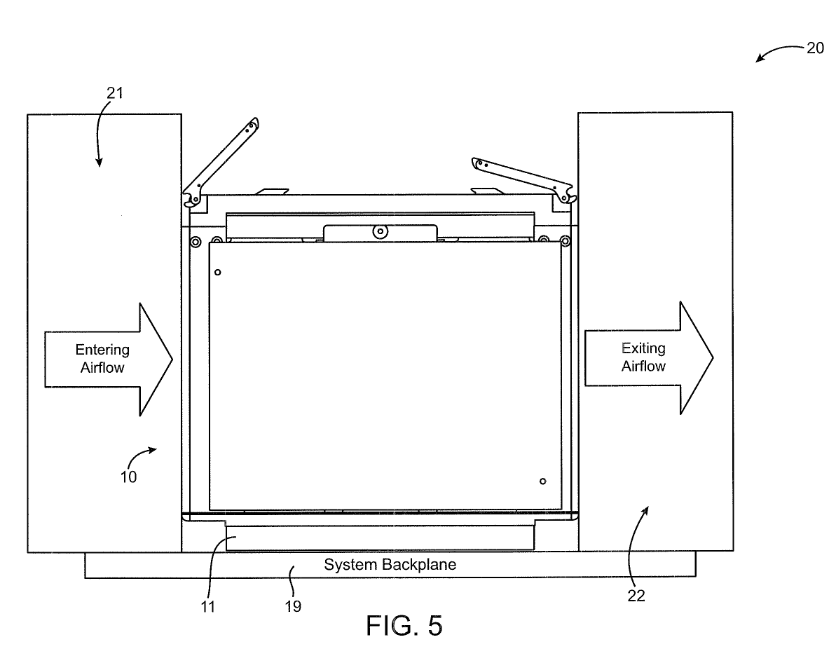

FIGS. 1A-1B show a front view and an isometric view, respectively, of an integral heat sink assembly 10, according to an embodiment of the invention. Further, FIG. 2 shows an exploded (disassembled) view of the integral heat sink 10. The integral heat sink assembly 10 includes a module connector 11 for connecting the heat sink to a system backplane 19 (FIG. 5), a left side card heat sink 12, a right side card heat sink 13, a left side circuit card high power component surface 14 (i.e., left electronics circuit board), a right side circuit card high power component surface 15 (i.e., right electronics circuit board), and a latching structure 16.

The card heats sinks 12, 13 are attached to the inside facing surface of electronics circuit boards 14, 15, respectively. Each card heat sink comprises a large finned heat sink 17, optimized to most efficiently transfer heat from the highest power component(s) on the corresponding circuit board, allowing cooling airflow travel in a channel 18 formed between the heat sink cards 12, 13.

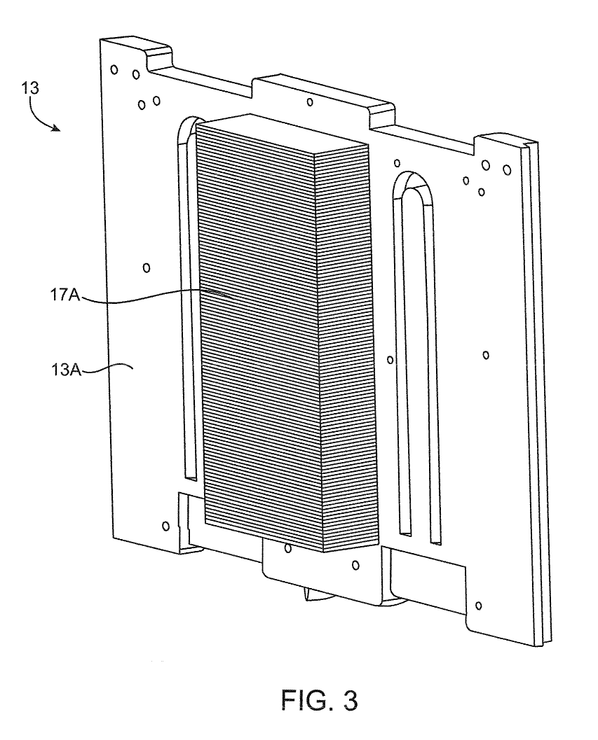

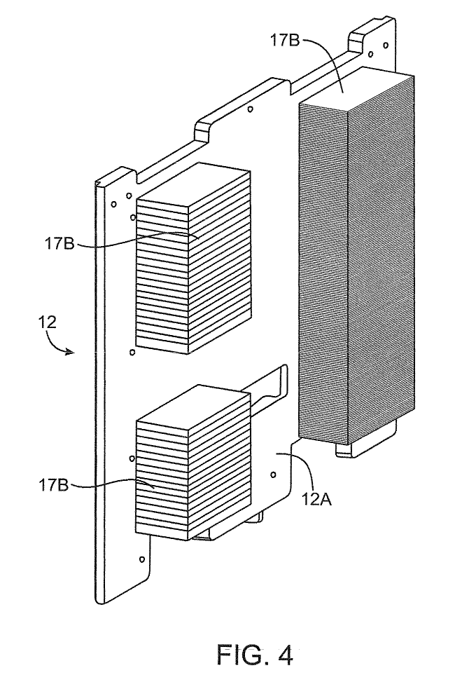

FIG. 3 shows a perspective view of the right side card heat sink 13 of the integral heat sink assembly 10, with optimized fin sections 17 over high power processor location(s) of the board 15. FIG. 4 shows a perspective view of the left side card heat sink 12 of the integral heat sink assembly, with optimized fin sections 17 over high power processor locations of the board 14 (e.g., four board corners).

In a preferred embodiment; the heat sink card 12 comprises a large high conductivity spreading plate 12A with one or more discrete high performance fin areas 17A located on the plate 12A. The heat sink card 13 comprises a large high conductivity spreading plate 13A with one or more discrete high performance fin areas 17B located on the plate 13A.

FIG. 5 shows an example module system (chassis rail structure) 20 in which an integral heat sink assembly 10 according to the invention is installed. The structure 20 includes chassis rail structure and air inlet plenum 21 and chassis rail structure and air outlet plenum 22, allowing airflow through the channel 18 in the heat sink assembly 10.

These fin areas 17 (i.e., 17A, 17B) are located relative to the most high power component(s) on the board(s) 14, 15, to provide essentially the most efficient thermal performance relative to the component(s) and to the rest of the module system 20 as a whole. Fins 17A emanating from the spreading plate 12A mounted to the boards 14, are nested in between the fins 17B emanating from the spreading plate 13A mounted to the opposing board 15, when the integral heat sink assembly 10 is assembled. This nesting allows the fin height to be maximized relative to the available gap between boards 14, 15.

Preferably, the fin sections 17A, 17B emanating from the board side heat spreader plate 12A, 13A, are optimized for most efficient airflow gap, pressure drop, and heat sink base spreading performance. Fin sections 17A, 17B are strategically placed directly over high power components on the boards 14, 15 to minimize spreading resistance in the heat sink base 11. Fin sections 17A, 17B are full height for the available depth of channel 18, wherein no fins emanate from the opposite side heat sink base 11. As such, the assembly 10 provides essentially maximized fin surface area for each local region of fins 17 from either heat sink plate.

Board component layouts are driven such that high power components on either board do not directly shadow each other. This provides highly effective air cooling for high power boards in essentially the smallest possible volumetric space.

The card heat sinks 12, 13 are attached together to create a modular structure 10 that integrates two high power circuit boards 14, 15 facing each other. The structure 10 provides all the features necessary for mounting flexible connectors to the backplane facing side of the structure 10. The structure 10 creates a sealed airflow channel 18 for directing a high volume of airflow through the high performance nested fin sections 17 at high pressure drop with minimal airflow leakage (FIG. 5). No additional airflow baffeling is needed.

The card heat sinks 12, 13 further provide rail guide features for directing the structure 10 into a chassis/backplane structure (FIG. 5). These features provide guidance to plug the structure 10 to the backplane and prevent leakage of airflow as cooling air enters the channel 18 in the structure from the chassis airflow supply plenum 21. The two large heat sinks 12, 13 further provide latching hardware features 16 for pre-loading the backplane interconnect and retaining the module within the system chassis.

The card heat sinks 12, 13, efficiently cool high power electronics circuit boards that are integrated into a single modular assembly. The high power components on each board face each other and require air cooled heat sinks attached to multiple high power components on the inward facing surfaces of both boards. The gap between the inward facing surfaces of the card heat sinks 12, 13 creates the channel 18 through which a well controlled quantity of cooling airflow can be channeled to remove the heat from the electrical components on each surface. The dimension for the gap and channel 18 is driven by balancing the quantity of air, pressure drop, and heat sink surface area needed to maintain the worst case component(s) temperature(s) below its maximum rating. Both cards 12, 13 connect to a common backplane connector via a common module side connector 11 that is attached via flex to the bottom edge of each board. The modular structure 10 fixes the location of each board relative to each other and the connector system at the bottom edge of the module. The integrated heat sinks 12, 13 for both boards provide the structural means to rigidly locate the two boards 14, 15 and connector system 11, 16 as a complete module assembly.

Those skilled in the art will appreciate that various adaptations and modifications of the just-described preferred embodiments can be configured without departing from the scope and spirit of the invention. Therefore, it is to be understood that, within the scope of the appended claims, the invention may be practiced other than as specifically described herein.

What is claimed is:

1. A method of heat sinking for multiple high power circuit board modules, comprising:
providing a compact nested fin integral heat sink assembly for each high power circuit board module; and
positioning fin sections on the heat sink assembly such that a plurality of nested fin sections emanate from each board side heat spreader plate of the assembly, thereby providing efficient airflow gap, pressure drop, and heat sink base spreading performance;
wherein the fin section can be placed essentially directly over high power components on each board module to minimize spreading resistance in a heat sink base of the assembly, the fin sections on each board module side providing channel depth without extending from an opposite side heat sink base, thereby increasing fin surface area for each local region of fins from either heat sink base.
